(19) United States
(12) Patent Application Publication
(10) Pub. No.: US 2007/0102553 A1
(43) Pub. Date: May 10, 2007

(54) Apparatus and method of adjusting distinct carrier tape

(75) Inventors: Yuan-Chi Lin, Hsin-Chu City (TW); Bob Huang, Hsin-Chu City (TW)

Correspondence Address: BIRCH STEWART KOLASCH & BIRCH, PO BOX 747, FALLS CHURCH, VA, 22040-0747, US

(73) Assignee: KING YUAN ELECTRONICS CO., LT

(21) Appl. No.: 11/223,326

(22) Filed: Sep. 9, 2005

(51) Int. Cl. H03C 3/09; G11B 23/107

(52) U.S. Cl. 242/348

(57) ABSTRACT

The present invention is directed to apparatus and method of adjusting distinct tape feeder. An image detector is arranged above the tape, and a mid-hole detector is utilized to detect the mid-hole of the tape. The image detector and the mid-hole detector are fixed a distance there between, wherein the distance is a common multiple of the various tape pitches.

### BACKGROUND OF THE INVENTION

1. Field of the Invention

The present invention relates generally to an apparatus of tape feeder, and more particularly to an apparatus or method which can fast adjusting a tape feeder to accommodate various carrier tapes of varying pitch, i.e., varying distance from one component to the next on the carrier tape.

2. Description of the Prior Art

After manufacturing, packaging and final testing, the Integrated Circuits (ICs) normally are packaged in a flexible carrier tape with pockets formed at regular intervals along its length, so that the ICs can be handled or picked-up easily. A tape and reel machine includes a plurality of tape feeder that can feed such carrier tapes. There are various types of ICs having different sizes, so that it is necessary to prepare many kinds of tape, and therefore it is necessary to adjust the tape feeder in accordance with various kinds of tape before advancing the tape. FIG. 1 shows a front view of conventional adjusting distinct apparatus for adjusting a tape feeder. An image detector 11 (a charge coupled device, CCD, may be used) is installed above the carrier tape 12, and it is employed for detecting the lack of pin or reverse orientation of the loaded ICs. Furthermore, a mid-hole detector 14 and a keyholes detector 15 are installed in the same side of the carrier tape near the image detector 11.

Two adjacent pockets, mid-holes 13 and keyholes 16 are laid out in the schematic vertical view provided in FIG. 2. One mid-hole 13 was perforated in the bottom of each pocket, and the pitch A of the tape, defined as the distance between the center of the two adjacent mid-holes 13. Pitches common in the industry are 8 mm, 12 mm, 16 mm and 20 mm. Perforated edge of the carrier tape includes keyholes 16, which generally are 4 mm apart from each other, and the distance between mid-hole 13 and keyhole 16 is 2 mm.

A carrier tape 12 with different pitch A is necessary due to differences in the type of ICs. Some adjustment must be done while a different carrier tape 12 has been set in the tape feeder. The conventional adjustment apparatus part shown in FIG. 1 includes three steps adjusting the tape feeder: (1) adjusting the position of the image detector 11, made the center of the image detector 11 to aim at the center of one mid-hole 13; (2) tuning the position of mid-hole detector 14 to get another mid-hole 13 is sensed by it; (2) adjusting the position of the carrier tape 12 in its latitude direction so that the keyholes 16 can be detected by keyhole-detector 15. The sequence of adjusting process is difficult, time consuming and tedious by using conventional tape feeder. In additional, the cost of the equipment and maintenance are much higher as too many detectors have been used in the conventional tape feeder.

Therefore, it would be an advantageous to have a novel apparatus and method that allow for fast adjusting the tape feeder, thereby speed up the adjustment, reduce the cost and increase the yield.

### SUMMARY OF THE INVENTION

It is one object of the present invention to provide an apparatus for adjusting the tape feeder, thereby speed up the adjustment, reduce the cost and increase the yield.

According to the object, the present invention provides an adjusting distinct apparatus of tape feeder, which includes an image detector arranged above the tape, and a mid-detector for detecting the mid-hole of the carrier tape. The distance between the image detector and mid-hole detector is fixed at a constant as well as a common multiple of pitches of various tapes.

According to another embodiment, the present invention provides a method for adjusting distinct the tape feeder. Aiming the center of an image detector at the center of one mid-hole, then fixing a distance between the image detector and a mid-hole detector, and the distance is a multiple of pitches of various tapes, and the whole adjustment is finished while another mid-hole is detected by the mid-hole detector.

### BRIEF DESCRIPTION OF THE DRAWINGS

FIG. 1 is a front view of conventional adjusting apparatus of tape feeder.

FIG. 2 is a vertical plan view of the position of the mid-hole and the position of the keyhole.

FIG. 3 is a front view of adjusting distinct apparatus according to one embodiment of the present invention.

FIG. 4 is side view schematically illustrating the mechanism of fine adjustment (switch) according to one embodiment of the present invention.

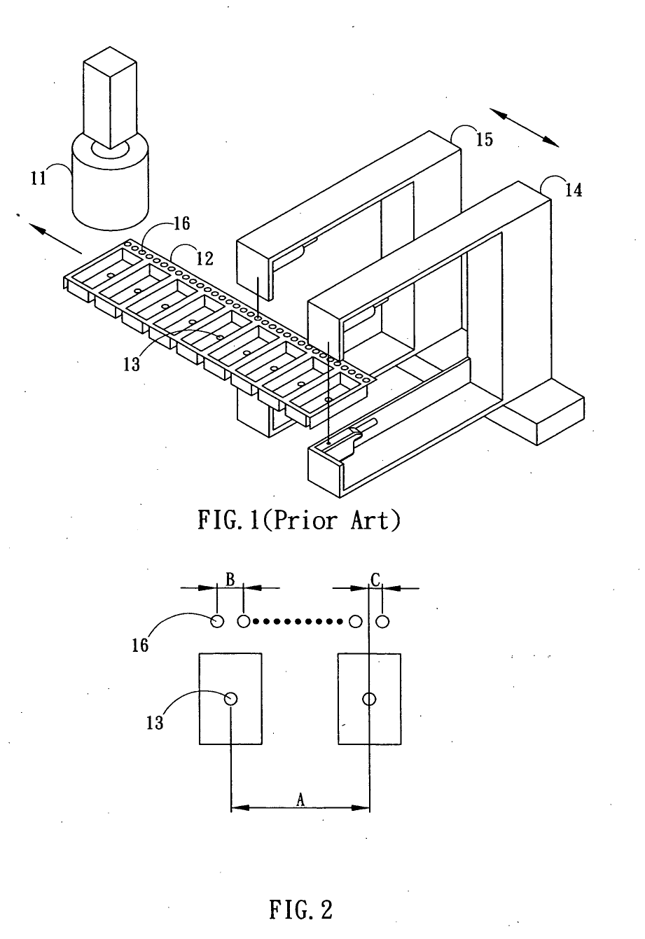

### DESCRIPTION OF THE PREFERRED EMBODIMENT

The detailed description of the present invention will be discussed in the following embodiments, which are not intended to limit the scope of the present invention, but can be adapted for other applications. While drawing are illustrated in details, it is appreciated that the quantity of the disclosed components may be greater or less than that disclosed, except expressly restricting the amount of the components.

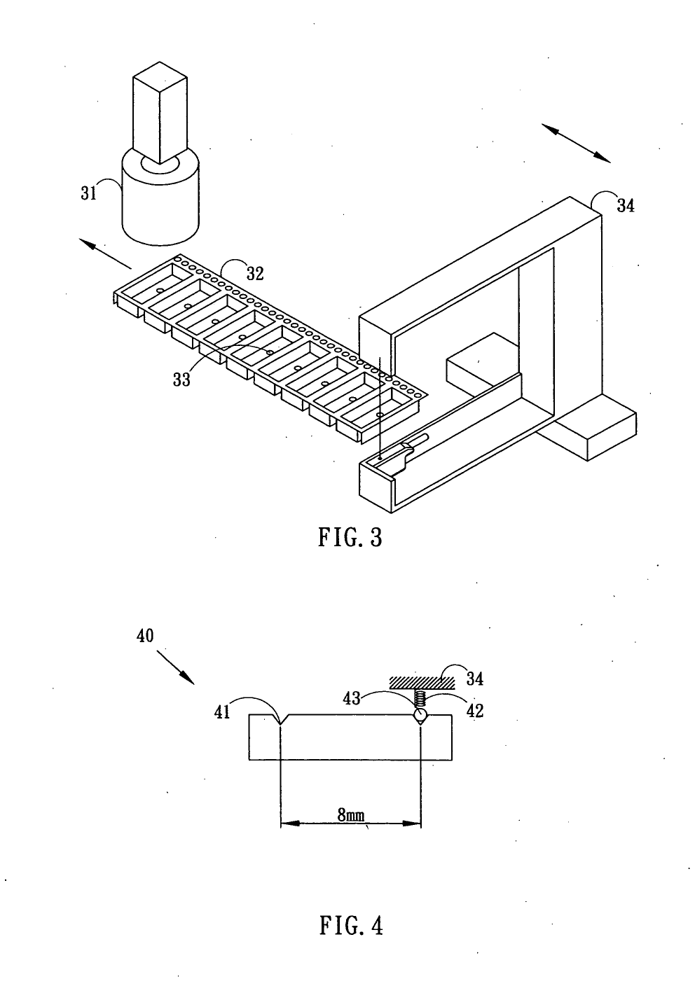

FIG. 3 shows the fast adjusting distinct apparatus and method for a tape feeder according to one embodiment of the present invention. An image detector 31 is arranged above the carrier tape 32, and its center is aimed at a line formed with a string of the centers of the mid-holes 33, and it can only moves in direction of the longitude of the carrier tape 32. The Charge Coupled Device (CCD) or other kinds of image detectors 31 such as Complementary Metal Oxide Semiconductor (CMOS) may be employed for adjusting the position and detecting the lack of the pin or reverse orientation of the loaded ICs.

A pair of mid-hole detectors 34 with a fixed distance apart from the image detector 31 is arranged above and under the carrier tape 32. The center of the mid-hole detector 34 is aimed at a line formed with a string of the centers of the mid-holes 33, and it can only moves in direction of the longitude of the carrier tape 32. The mid-hole detector 34 consists of an emitter (such as infrared ray emitter) and a sensor, and it can be implemented in a number of ways in a preferred embodiment of the present invention. The emitter 34, mid-hole 33 and sensor 34 are arranged in a row, the light (visible or invisible) emitted by emitter passes through the mid-hole 33, and sensed by the sensor 34. The circuit in interior of the mid-hole detector 34 will be actuated to the on state if the light was sensed by the sensor 34; and the circuit will stay on the off state if the light is not sensed by the sensor. Please note that the mid-hole detector 34 is arranged above and under the carrier tape 32 in this embodiment of the present invention, but both emitter and sensor could be arranged in the same side of the carrier tape 32 in others embodiments of the present invention. In such case the sensor will not sense the light because the light passes through the mid-hole, cause the off state; and the sensor will sense the light reflect off from IC or tape if one IC has been loaded, cause the on state.

There are various kinds of the carrier tapes, and pitches common in the industry are 8 mm, 12 mm, 16 mm and 20 mm. According to this embodiment of the present invention, take a common multiple of the 8, 12 and 20 and considering the space for easily operating, the distance between the image detector 31 and mid-hole detector 34 is fixed purposely at 360 mm. The carrier tape 32 with 16 mm pitch is to regard as a special case in this embodiment and will be explained later. The other distances may be chosen according to requirement of specific operating space, but must a common multiple of the 8, 12 and 20. If the major specification is no longer 8, 12 and 20 mm in the future, the distance shall be changed to another common multiple of the varying tape pitches, according to the same theory.

Because the distance between the image detector 31 and the mid-hole detector 34 is kept constant as well as it is a common multiple of 8, 12, and 20. Therefore, only one adjustment step is needed prior advancing the tape if one of the above tapes has set in the tape feeder, that is, adjusting the center of the image detector 31 to aim at the center of the mid-hole 33, and the mid-hole detector 34 will also detect the mid-hole 33 simultaneously. As the image detector 31 and the mid-hole detector 34 can only move in the direction of the longitude of the tape, so that their center and the mid-holes is arranged on the same plane all the time, therefore there is no further latitude adjustment of the tape needed, and consequently the conventional keyholes detector 15 could be cancelled. The adjustment according to the present invention is faster, the cost is lower and the space needed is smaller than the conventional adjusting apparatus. Moreover, it is easy to adjust to the tape feeder when other tapes will be used according to the present invention. For example, set the parameter of the controller (comprise motor and its firmeware/software) in accordance with the specification of the carrier tape, adjust the image detector 31 to aim at one mid-hole 33, and the mid-hole detector will also detect another mid-hole simultaneously, and all pre-setting before advancing the tape is finished.

According to the preferred embodiment hereinbefore, the distance between the image detector 31 and the mid-hole detector 34 depend on a common multiple of the 8 mm, 12 mm and 20 mm carrier tapes 32; however, the 16 mm carrier tape 32 not mentioned yet. Because 360 mm is not a multiple of 16 mm, therefore a further fine-tune mechanism 40 (also called a switch mechanism) is provided for handling the 16 mm pitch tape. FIG. 4 schematically illustrate the side view of the fine-tune mechanism. Two V-cut are provided, which are 8 mm apart from each other in the depicted example; The distance 8 mm was evaluated by the formula: 360−352=8, where the 352 is a multiple of 16 (16×22=352) as well as the nearest number approaches the number 360. An anchoring ball 43 and a spring 42 coupling to the bottom of the mid-hole detector 34 are mounted between the mid-hole detector 34 and the fine-tune mechanism 40, they are employed for moving and anchoring the mid-hole detector 34. If the 16 mm carrier tape 32 has replaced, the adjustment process prior to advancement is change the position of the mid-hole detector 34 from one V-cut 41 to the other V-cut 41, accordingly, the distance between the image detector 31 and the mid-hole detector 33 become 352 mm (360−8=352). The rest of the process need adjusting the tape feeder is the same as before, adjust the image detector to aim at the mid-hole, and the mid-hole detector 34 will also detect the mid-hole 33 simultaneously.

The V-cut 41, spring 42 and anchoring ball 43 are employed in this embodiment of the present invention. However, other switch mechanism having different structure may be used in other embodiments according to the present invention as long as a constant distance will be kept between the two anchoring positions of the switch mechanism. Furthermore, the fine-tune mechanism 40 is installed under the mid-hole detector 34 in this embodiment, however, it will also practicable if the fine-tune mechanism is installed under the image detector 31. In other words, the distance between the image detector and the mid-hole detector can be fine tuned by adjusting the position of the image detector 31 according to the same theory.

While the invention has been described in conjunction with a specific mode, it will be appreciated by those skilled in the art that various modifications, alternatives and variations may be made without departing from the scope of the present invention, which intended to be limited solely by the appended claims.

What is claimed is:

1. An adjusting distinct apparatus of tape feeder for adjusting various carrier tapes, which includes pockets with a mid-hole in its bottom, comprising:
an image detector which is installed above the tape; and
an mid-hole detector for detecting the mid-hole, and the distance between the image detector and the mid-hole detector is kept constant as well as a common multiple of specifications of the various tapes.

2. The adjusting distinct apparatus according to claim 1, wherein said image detector comprises a Charge Coupled Device (CCD).

3. The adjusting distinct apparatus according to claim 1, wherein the center of said image detector is aimed at the center of the string of mid-holes, and it can only move in direction of the longitude of the tape all the time.

4. The adjusting distinct apparatus according to claim 1, wherein said mid-hole detector comprises an emitter and a sensor, which are installed above and under the tape respectively.

5. The adjusting distinct apparatus according to claim 1, wherein said specification of the various tapes is pitch, which is the distance from one pocket to the next along the carrier tape.

6. The adjusting distinct apparatus according to claim 5, wherein said various tape pitches are 8, 12, 20 mm respectively.

7. The adjusting distinct apparatus according to claim 6, wherein said distance between the image detector and the mid-hole detector is a common multiple of said various tape pitches.

8. The adjusting distinct apparatus according to claim 7, wherein said distance between the image detector and the mid-hole detector is 360 mm.

9. The adjusting distinct apparatus according to claim 1, further comprising a switch mechanism for tuning the distance between said image detector and said mid-hole detector.

10. The adjusting distinct apparatus according to claim 9, wherein said switch mechanism is employed for moving the position of said mid-hole detector.

11. The adjusting distinct apparatus according to claim 10, wherein said switch mechanism comprises:
a base with two V-cut on it;
an anchoring ball, located in one of said two V-cut; and a spring with one terminal connected to said anchoring ball, and the other terminal connected to said mid-hole detector.

12. The adjusting distinct apparatus according to claim 11, wherein the distance between said two V-cut is the distance between said image detector and said mid-hole detector, subtracted by a multiple of said specification of the various tape.

13. An adjusting distinct method of tape feeder for adjusting various carrier tapes, which includes pockets with a mid-hole in its bottom, comprising:
aiming the center of an image detector at the mid-hole;
fixing a distance between said image detector and a detector, and the distance is a common multiple of the specifications of various tapes; and
detecting another mid-hole by the mid-hole detector until it is detected.

14. The adjusting distinct method according to claim 13, wherein said image detector comprises a Charge Coupled Device (CCD).

15. The adjusting distinct method according to claim 13, wherein said mid-hole detector comprises an emitter and a sensor, which are installed above and under the tape respectively.

16. The adjusting distinct method according to claim 13, wherein said specification of the various tapes is pitch defined as the distance from one pocket to the next along the carrier tape.

17. The adjusting distinct method according to claim 16, wherein said various tape pitches are 8, 12, 20 mm respectively.

18. The adjusting distinct method according to claim 17, wherein said distance between the image detector and the mid-hole detector is a common multiple of said various tape pitches.

19. The adjusting distinct method according to claim 18, wherein said distance between the image detector and the mid-hole detector is 360 mm.

20. The adjusting distinct method according to claim 13, further comprising a switch method for tuning the distance between said image detector and said mid-hole detector.

21. The adjusting distinct method according to claim 20, wherein said switch method is switching the position of said mid-hole detector.
